(19) United States
(12) Patent Application Publication
(10) Pub. No.: US 2025/0199906 A1
(43) Pub. Date: Jun. 19, 2025

(54) METHOD AND APPARATUS FOR FLEXIBLE ON-CHIP MEMORY CONFIGURATION TO SUPPORT MULTIPLE ERROR DETECTION AND CORRECTION MECHANISMS

(71) Applicant: Marvell Asia Pte Ltd, Singapore (SG)

(72) Inventors: Anh Nguyen, Ho Chi Minh City (VN); Duc Tran, Ho Chi Minh City (VN); Hoang Son Le, Ho Chi Minh City (VN)

(21) Appl. No.: 18/893,070

(22) Filed: Sep. 23, 2024

Related U.S. Application Data
(60) Provisional application No. 63/612,328, filed on Dec. 19, 2023.

(51) Int. Cl. G06F 11/10

(52) U.S. Cl. CPC G06F 11/1044

(57) ABSTRACT

A new approach is proposed that contemplates system and method to support multiple error detection and/or correction mechanisms via flexible on-chip memory (OCM) configurations. Here, an OCM includes a plurality of memory banks, wherein each of the plurality of memory banks includes a plurality of memory instances. Under the proposed approach, a first subset of the plurality of memory banks are configured to support a first type of error detection and/or correction mechanism while a second subset of the plurality of memory banks are configured to support a second type of error detection and/or correction mechanism. Moreover, a subset of memory instances within one or more of the plurality of memory banks are configured to store data and extra code words at the same time in order to efficiently support a specific type of error detection and/or correction mechanism.

### RELATED APPLICATION

This application is a nonprovisional application and claims the benefit and priority to a provisional application No. 63/612,328 that was filed on Dec. 19, 2023, which is incorporated herein by reference in its entirety.

### BACKGROUND

Single bit Error Correction Double bit Error Detection (SECDED) is a standard error detection and correction mechanism that can correct 1-bit error (single bit error Correction or SEC) and detect up to 2-bit errors (double bit error detection or DED). SECDED (n, k)s are types of SECDED mechanisms often used to protect a memory against soft errors, wherein n is the actual data bit size and k is the extra code word (e.g., ECC) size for the data. In critical applications such as data-center, all on-chip memories (OCMs) such as SRAMs support the SECDED mechanisms. Deciding which type of SECDED (n, k) mechanism to use, however, is typically a trade-off between chip area overhead, performance, and product reliability. For non-limiting examples, SECDED (64,8) incurs 12.5% chip area overhead, while SECDED (128,9) incurs 7% chip area overhead. Such overhead difference cannot be ignored for large size OCMs. On the other hand, OCMs supporting SECDED (64,8) offer higher throughput than OCMS supporting SECDED (128,9) because SECDED (64,8) requires a read-modify-write (RMW) operation for all write operations with a size of less than 64 bits while SECDED (128,9) only requires a RMW operation for write operations with a size of less than 128 bits. Furthermore, SECDED (64,8) is more robust than SECDED (128,9) because it can correct up to 2-bit of errors within 128-bit data while SECDED (128,9) can only correct 1-bit. Supporting multiple SECDED mechanisms, however, is a technical challenge due to the complexity of an OCM controller to control access to the OCMs.

While the SECDED mechanisms are widely used, parity is another error detection mechanism that can be used to protect an OCM in some cases such as when the OCM is used as a data buffer. Parity (n) represents a parity mechanism where 1-bit parity code bit is added for n-bit data. In some embodiments, parity mechanisms can detect more errors than the SECDED mechanisms while the SECDED mechanisms can also perform error corrections. For example, Parity (8) requires the same number of code words for 64-bit data as SECDED (64,8), wherein Parity (8) can detect up to 8-bit errors within 64-bit of data while SECDED (64,8) can detect up to 2-bit errors. Similarly, Parity (16) requires almost the same number of code words for 128-bit data as SECDED (128,9).

The foregoing examples of the related art and limitations related therewith are intended to be illustrative and not exclusive. Other limitations of the related art will become apparent upon a reading of the specification and a study of the drawings.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts an example of a diagram of a system to support multiple error detection and/or correction mechanisms via flexible OCM configurations according to one aspect of the present embodiments.

FIG. 2 depicts an example illustrating a configuration of an OCM to support multiple error detection and/or correction mechanisms according to one aspect of the present embodiments.

FIG. 3A depicts an example of an interleaving memory bank mapping scheme of an initiator address space according to one aspect of the present embodiments; FIG. 3B depicts an example of a fixed memory bank mapping scheme of the initiator address space according to one aspect of the present embodiments.

FIG. 4A depicts an example of configuration of one of the memory banks of FIG. 2 configured to support SECDED (128, 9) according to one aspect of the present embodiments; FIG. 4B depicts an example of configuration of one of the memory banks of FIG. 2 configured to support SECDED (64, 8) according to one aspect of the present embodiments; FIG. 4C depicts another example of configuration of one of the memory banks of FIG. 2 configured to support SECDED (64, 8) according to one aspect of the present embodiments; FIG. 4D depicts an example of another configuration of one of the memory banks of FIG. 2 configured to support SECDED (64, 8) according to one aspect of the present embodiments.

FIG. 5A depicts an example of configuration of one of the memory banks of FIG. 2 configured to support Parity (16) according to one aspect of the present embodiments; FIG. 5B depicts an example of configuration of one of the memory banks of FIG. 2 configured to support either Parity (8) or SECDED (64, 8) according to one aspect of the present embodiments.

FIG. 6 depicts a flowchart of an example of a process to support multiple error detection and/or correction mechanisms via flexible OCM configurations according to one aspect of the present embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Before various embodiments are described in greater detail, it should be understood that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements in any of several other embodiments described herein. It should also be understood that the terminology used herein is for the purpose of describing the certain concepts, and the terminology is not intended to be limiting. Unless defined otherwise, all technical and scientific terms used herein have the same meaning as commonly understood in the art to which the embodiments pertain.

A new approach is proposed that contemplates system and method to support multiple error detection and/or correction mechanisms via flexible OCM configurations. Here, an OCM includes a plurality of memory banks, wherein each of the plurality of memory banks includes a plurality of memory instances. Under the proposed approach, a first subset of the plurality of memory banks are configured to support a first type of error detection and/or correction mechanism while a second subset of the plurality of memory banks are configured to support a second type of error detection and/or correction mechanism. Moreover, a subset of memory instances within one or more of the plurality of memory banks are configured to store data and extra code words at the same time in order to efficiently support a specific type of error detection and/or correction mechanism.

By configuring memory banks and their memory instances of an OCM to support multiple error detection and/or correction mechanisms, the proposed approach may reduce the chip area by opting for a lower overhead error detection and/or correction mechanism as a default. When necessary, the OCM is re-configured to support a higher overhead error detection and/or correction mechanism in order to achieve higher throughput, higher protection (or better reliability) but with less useable memory space. Additionally, an OCM supporting multiple error detection and/or correction mechanisms makes hard hardware tampering more difficult because the hacker does not know which error detection and/or correction mechanism is being used. Furthermore, switching between different error detection and/or correction mechanisms, e.g., in automotive applications where memory is required to test and replace during operation, may help to extend lifetime of the memory as only software/firmware needs to be updated to work with less memory space.

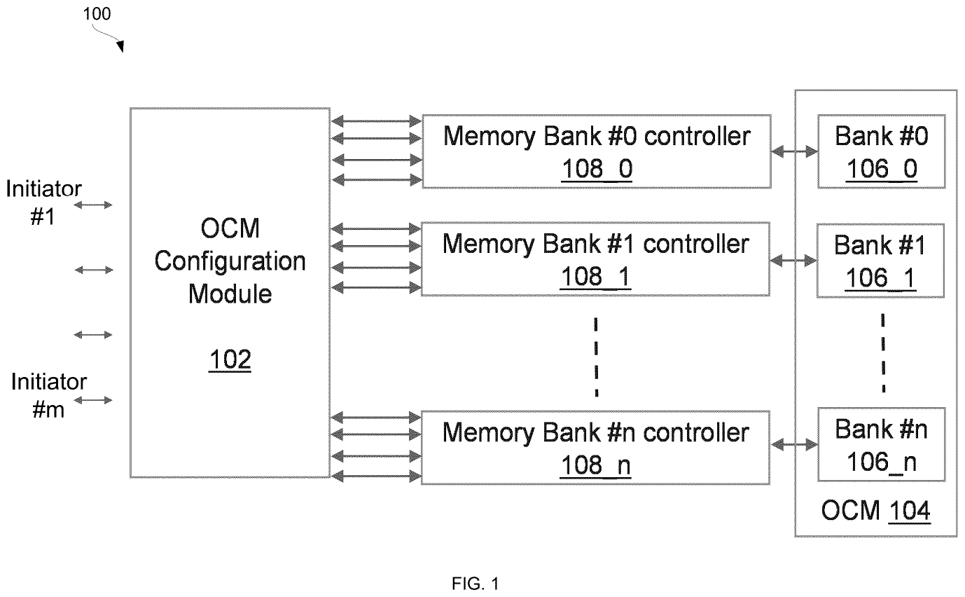

FIG. 1 depicts an example of a diagram of a system 100 to support multiple error detection and/or correction mechanisms via flexible OCM configurations. Although the diagrams depict components as functionally separate, such depiction is merely for illustrative purposes. It will be apparent that the components portrayed in this figure can be arbitrarily combined or divided into separate software, firmware and/or hardware components. Furthermore, it will also be apparent that such components, regardless of how they are combined or divided, can execute on the same host or multiple hosts, and wherein the multiple hosts can be connected by one or more networks.

In the example of FIG. 1, the system 100 includes an OCM configuration module 102, an OCM 104 that comprises a plurality of memory banks (including bank #0, bank #1, up to bank #n; where n is an integer allocated at the discretion of the system 100 designer) 106s, and a plurality of memory controllers 108s each configured to control access to at least one of the plurality of memory banks 106s of the OCM 104. It is appreciated that each of the module and/or controllers in the system 100 can be one or more computing units or devices, each with software instructions stored in a storage unit such as a non-volatile memory of the computing unit for practicing one or more processes. When the software instructions are executed, at least a subset of the software instructions is loaded into memory by one of the computing units, which becomes a specially purposed one for practicing the processes. The processes may also be at least partially embodied in the computing units into which computer program code is loaded and/or executed such that the computing units become special purpose computing units for practicing the processes.

In the example of FIG. 1, memory type of the OCM 104 can be but is not limited to static random-access memory (SRAM). Although SECDED (n, k) mechanisms (e.g., SECDED (128,9) and SECDED (64,8)) and Parity (n) mechanisms (e.g., Parity (8) and Parity (16)) are used as non-limiting examples to illustrate the proposed approach in the discussions below, same or similar approaches can also be applied to other types of error detection and/or correction mechanisms as understood by one ordinarily skilled in the art.

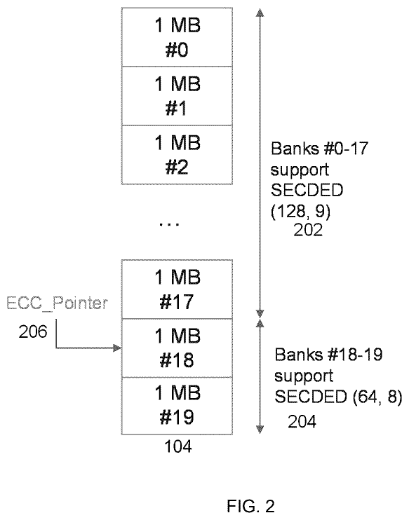

In the example of FIG. 1, the OCM configuration module 102 is configured to configure the OCM 104 to support a plurality of initiators each utilizing one or more error detection and/or correction mechanisms for its address space (e.g., an initiator address space). In some embodiments, the OCM configuration module 102 is configured to designate and configure a first set of the plurality of memory banks 106 in the OCM 104 to support a first error detection and/or correction mechanism. The OCM configuration module 102 also designates and configures a second set of the plurality of memory banks 106s in the OCM 104 to support a second error detection and/or correction mechanism. In some embodiments, the first set of the plurality of memory banks 106 and/or the second set of the plurality of memory banks 106 are each distributed across the OCM 104. In some embodiments, the first set of the plurality of memory banks 106 and/or the second set of the plurality of memory banks 106 are continuous memory banks in the OCM 104. FIG. 2 depicts an example illustrating a configuration of the OCM 104 to support multiple error detection and/or correction mechanisms. As shown by the example of FIG. 2, the OCM 104 of 20 MB memory has 20 memory banks 106s each having 1 MB of memory. The OCM configuration module 102 designates and configures a first set 202 of memory banks #0-17 in the OCM 104 to support SECDED (128, 9) and a second set 204 of memory banks #0-17 in the OCM 104 to support SECDED (64, 8), respectively.

In some embodiments, when the first set of the plurality of memory banks 106 and the second set of the plurality of memory banks 106 are continuous memory banks in the OCM 104, the OCM configuration module 102 is configured to program/configure a pointer 206 (e.g., an ECC_pointer) to one of the plurality of memory banks 106s to mark separation between the first set and the second set of the memory banks supporting the first and the second error detection and/or correction mechanisms, respectively. For a non-limiting example, if the pointer 206 is equal to 18 as shown in FIG. 2, it marks that the first set 202 of the memory banks #0-17 supports SECDED (128, 9) and the second set 204 of the memory banks #18-19 supports SECDED (64, 8). In some embodiments, the OCM configuration module 102 is configured to set the pointer 206 in such way that the plurality of memory banks 106s in the OCM 104 are configured to support a single error detection and/or correction mechanism. For example, if pointer 206 is equal to 0, all of the plurality of memory banks 106 are configured to support SECDED (64, 8). If, on the other hand, pointer 206 is equal to 20 (or any number greater than the number of memory banks 106 in the OCM 104), all of the plurality of memory banks 106 support SECDED (64, 8).

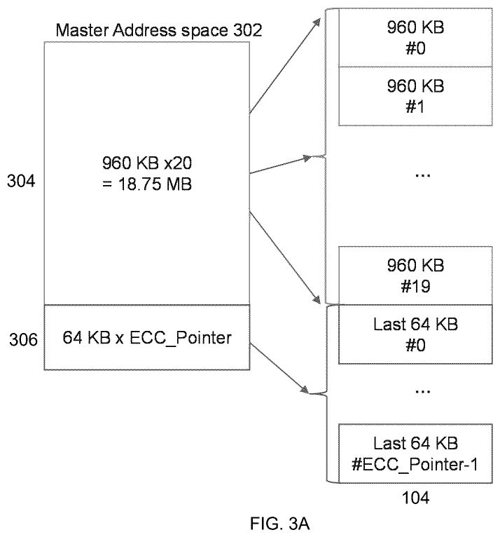

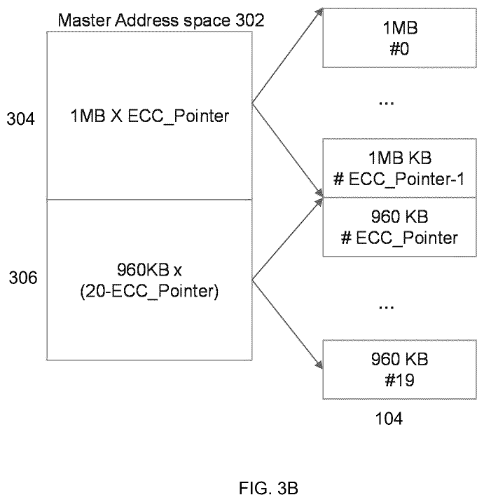

Since different error detection and/or correction mechanisms may result in different usage memory within each memory bank, the pointer 206 affects the total usable memory space in the OCM 104, which may range from 18.75 MB to 20 MB (in 64 KB granularity) for the OCM 104 of 20 MB in size. In some embodiments, the OCM configuration module 102 is configured to map an initiator address space to the plurality of memory banks 106s based on the programmable pointer 206. Here, the initiator address space is an address space of an initiator, which utilizes one or more error detection and/or correction mechanisms. In some embodiments, the OCM configuration module 102 supports multiple memory bank mapping schemes of the initiator address space. FIG. 3A depicts an example of an interleaving memory bank mapping scheme of the initiator address space. As shown by the example of FIG. 3A, the first portion 304 (e.g., full_interleaving_size=18.75 MB) of the initiator address space 302 is interleavingly mapped to the first 960 KB of each of the 20 memory banks. The second/last address space 306 (if needed) is interleavingly mapped among a “ECC_Pointer” number of banks each of 64 KB in size. If an initiator address is less than the full_interleaving_size (e.g., 18.75 MB), it is mapped to a bank number that equals the initiator address MOD 20, at an offset that equals initiator address DIV 20. Otherwise, the initiator address is only interleavingly mapped among those banks that support, e.g., SECDED (128,9) mechanism, wherein the bank #=the initiator address MOD ECC Pointer at an offset=960 KB+(initiator address−full_interleaving_size) DIV ECC Pointer. If ECC Pointer is set to 20, the initiator address is full interleaved within the 20 MB usable space because both formulas are the same. If ECC_Pointer is set to 10, the initiator address is interleaved among 20 memory banks for the first portion 304 (e.g., 18.75 MB) of the initiator address space 302 and interleaved between 10 banks of the second portion 306 of the initiator address spaces (e.g., 640 KB) for a total useable space of 19.375 MB.

FIG. 3B depicts an example of a fixed memory bank mapping scheme of the initiator address space. As shown by the example of FIG. 3B, the first portion 304 (e.g., full fix size=1 MB*ECC_Pointer) of the initiator address space 302 is sequentially mapped from bank #0 to #(ECC_Pointer-1), wherein the second/last address space 306 (if needed) is simply mapped to (20-ECC_Pointer) number of banks each of 960 KB in size. If an initiator address is less than the full_fix_size, it is mapped to bank #=the initiator address DIV 1024 KB at an offset=the initiator address [19:0]. Otherwise, the initiator address is mapped to bank #=ECC_Pointer+(initiator address−full_fix_size) DIV 960 KB at an offset=initiator address[19:0]+(initiator address−full_fix_size) DIV 15)*64 KB. Note that DIV, *by 2ⁿ operations can be implemented using simple shifted operation.

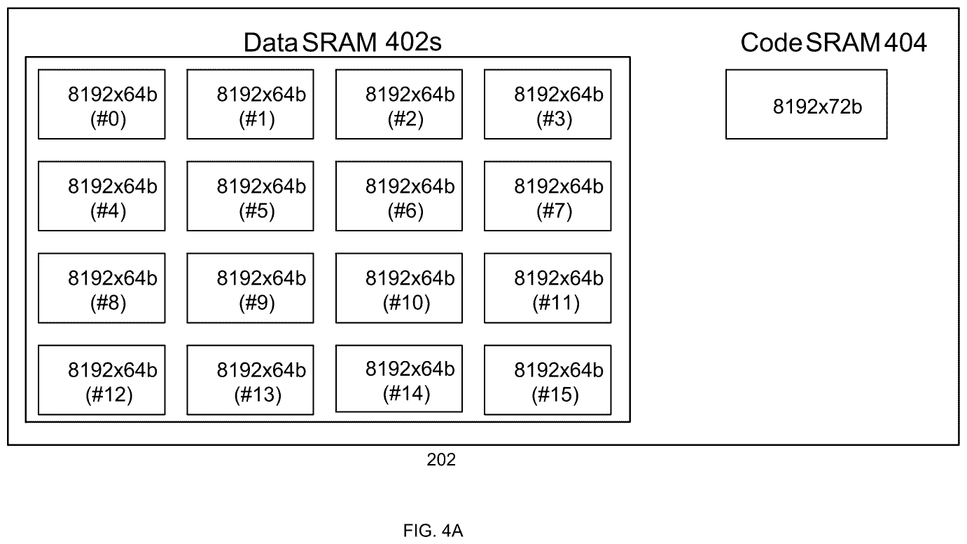

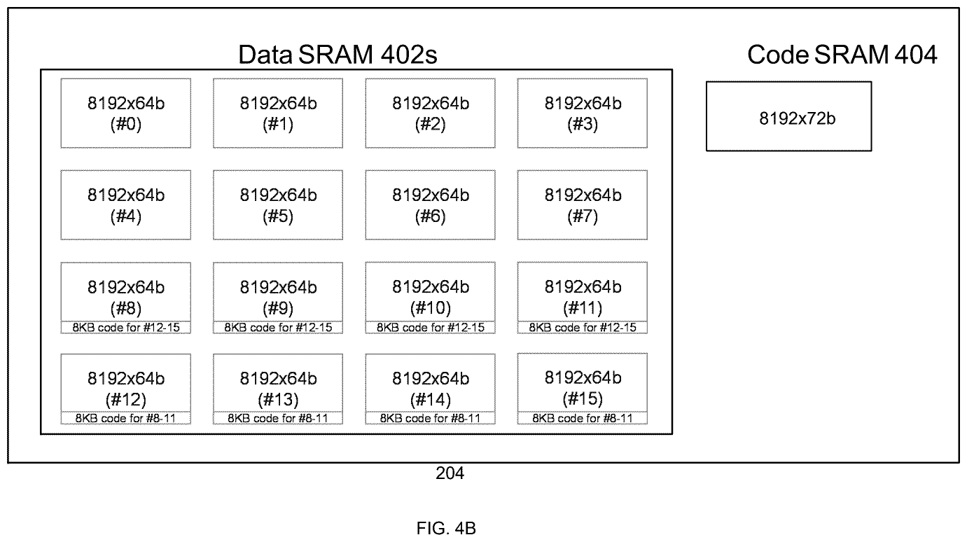

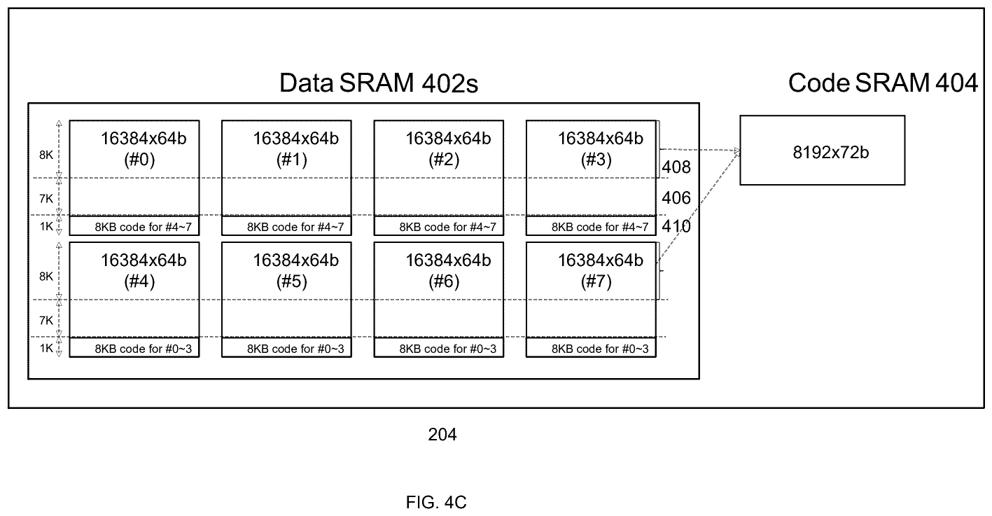

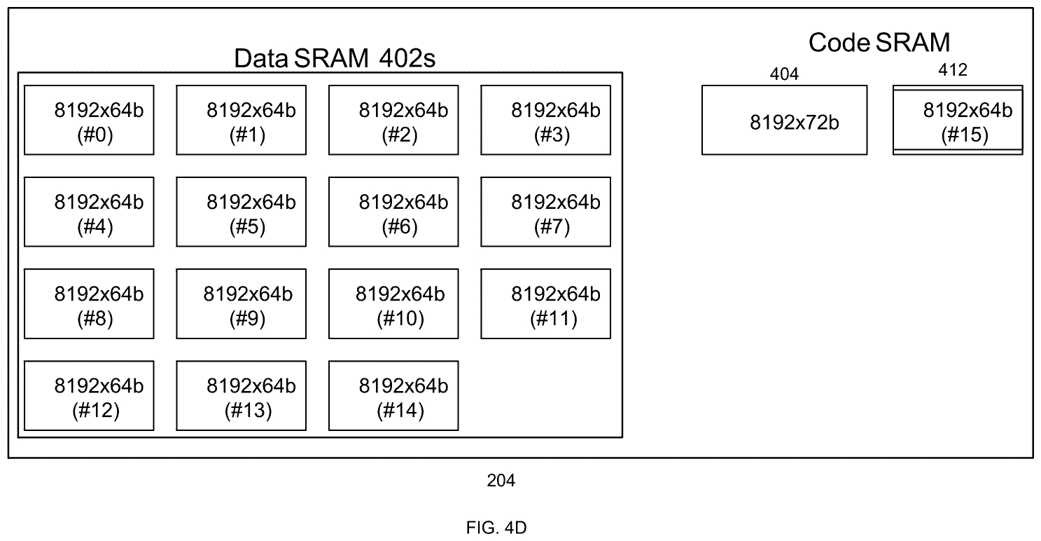

In some embodiments, one or more of the plurality of memory banks 106s comprise a plurality of memory instances configured to store data and the corresponding set of code words to support an error detection and/or correction mechanism. FIG. 4A depicts an example of configuration of one of the memory banks 202s of FIG. 2 configured to support SECDED (128, 9). As shown by the example of FIG. 4A, the memory bank includes 16 data memory (e.g., SRAM) instances 402s each of 8192×64 bit in size totaling 1 MB to store data plus one memory instance 404 of 8192×72 bit or 72 KB in size to store code words for the data. For a non-limiting example, for each 72-bit code word in the memory instance 404, bits [8:0] are used to store code associated with data stored in #0 and #1 data instances, bits [17:9] are used to store code associated with data stored in #2 and #3 data instances, etc. Such a memory instance configuration enables a burst access size of 256 bits with a maximum of 5 memory instances (4 data instances and one code instance) being activated in one cycle.

FIG. 4B depicts an example of configuration of one of the memory banks 204s of FIG. 2 configured to support SECDED (64, 8). Similar to the memory configuration of FIG. 4A, the memory bank also includes 16 data memory instances 402s each of 8192×64 bit in size to store data plus one memory instance 404 of 8192×72 bit to store code words for the data. In some embodiments, the OCM configuration module 102 is configured to support both the code words and the data in a same memory instance by assigning 64 KB of data memory instances 402s of the memory bank 204 as extra spaces to store code words in addition to the code word instance 404. As a result, size of the data memory is reduced to 1 MB−64 KB=960 KB while size of the code memory is increased to 136 KB. As a result, the system has less data memory but gets higher throughput, and higher level of error protection when necessary. For a non-limiting example, for each 72-bit code word in the code word memory instance 404, bits [7:0] are used to store code words associated with data stored in #0 data memory instance, bits [15:8] are used to store code words associated with data stored in #1 data instance, and bits [63:56] are used to store code words associated with data stored in #7 data instance while bits [71:64] are not used. In some embodiments, the OCM configuration module 102 is configured to assign certain size (e.g., 8 KB) from each of a subset of data memory instances 402s to store a total of 64 KB of extra code words. As shown by the example of FIG. 4B, the last 8 KB of data memory instances #8 to #15 are used to store code words interleavingly so that when data in memory instances #8-11 are accessed (to support 256b bus operation), one of data memory instances #12-15 can be accessed to access the code word stored there. As such, as in the case of SECDED (128, 9) discussed above, the number of maximum memory instances to be activated is fixed at 5 even though code words are stored inline with data.

As chip manufacturing processes advance, OCM density also increases, resulting in fewer number of memory instances and less chip area. FIG. 4C depicts another example of configuration of one of the memory banks 204s of FIG. 2 configured to support SECDED (64, 8). Unlike the memory configuration of FIG. 4B, the memory bank includes 8 data memory instances 402s each of 16384×64 bit in size to store data plus one memory instance 404 of 8192×72 bit to store code words for the data. As shown by the example of FIG. 4C, the last 8 KB of data memory instances #0 to #7 are used to store code words. In some embodiments, the OCM configuration module 102 is configured to allocate/assign certain un-used memory space (e.g., 8 KB) 406 between the data 408 and the extra code words 410 of each of the data memory instances 402s to have a “safe-guard” between the data 408 and the extra code words 410.

In some embodiments, more than one memory instances can be assigned to store code words for the data. FIG. 4D depicts an example of another configuration of one of the memory banks 204s of FIG. 2 configured to support an error detection and/or correction mechanism, which can be but is not limited to, SECDED (64, 8). As shown by the example of FIG. 4D, the memory bank includes 15 data memory instances 402s each of 8192×64 bit in size to store data, one memory instance 404 of 8192×72 bit plus one more memory instance 412 of 8192×64 bit in size to store code words for the data. For a non-limiting example, the additional memory instance 412 of 8192×64 bit may be configured to store the code words as follows: bits [7:0] are used to store code associated with data stored in #8 data memory instance, bits [15:8] are used to store code associated with data stored in #1 data memory instance, and bits [55:48] are used to store code associated with data stored in #14 while bits [63:56] are not used.

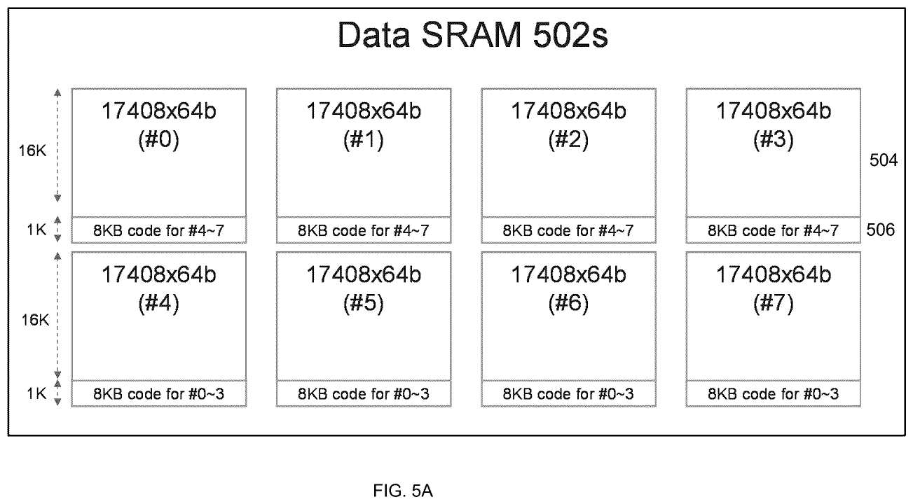

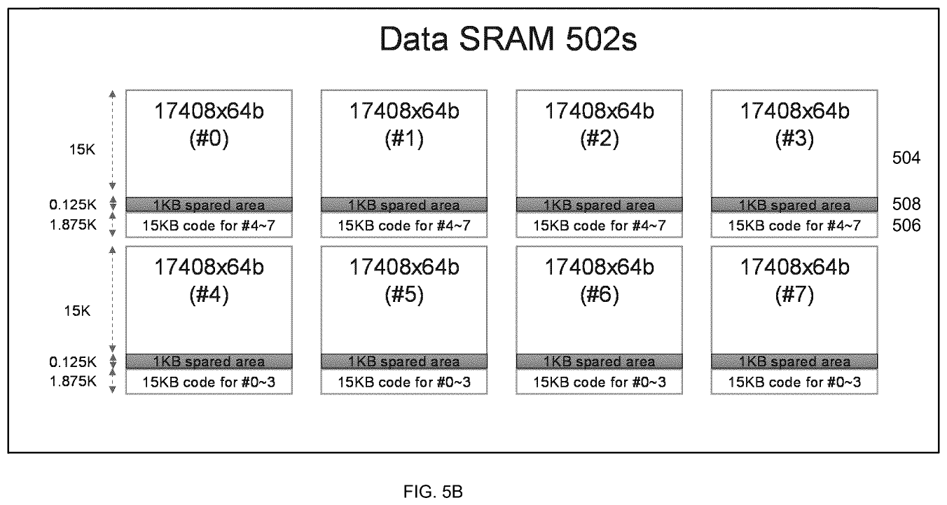

Since the code words required for Parity (8) and Parity (16) are the same or almost the same as SECDED (64,8) and SECDED (128,9), respectively, in some embodiments, the OCM configuration schemes for SECDED (64,8) and SECDED (128,9) discussed above can also be applied to Parity (8) and Parity (16), respectively. As such, the OCM configuration module 102 is configured to designate and configure the plurality of memory banks 106 in the OCM 104 to support multiple of the error detection and/or correction mechanisms, e.g., SECED and/or parity, at the same time. As such, it is possible to embed the code-words into the data to reduce memory instances and save area as discussed below if certain mechanism, e.g., SECDED (128,9), is not supported. FIG. 5A depicts an example of configuration of one of the memory banks of FIG. 2 configured to support Parity (16). As shown by the example of FIG. 5A, the memory bank includes 8 data memory instances 504s each of 17408×64 bit in size to store 128 KB of data 506 plus 8 KB code words 504, totaling 1 MB of data and 64 KB of code words. FIG. 5B depicts an example of configuration of one of the memory banks of FIG. 2 configured to support either Parity (8) or SECDED (64, 8). As shown by the example of FIG. 5B, the OCM configuration module 102 is configured to allocate/assign certain un-used/spare memory space (e.g., 1 KB) 508 between 120 KB of data 504 and 15 KB of code words 506 in each of the 8 data memory instances 502s 17408×64 bit in size, totaling 960 KB of data, 8 KB of unused space, and 120 KB of code words. Here, the un-used memory space 508 creates a “safe-guard” between the data 504 and the code words 506 as in the example of FIG. 4C.

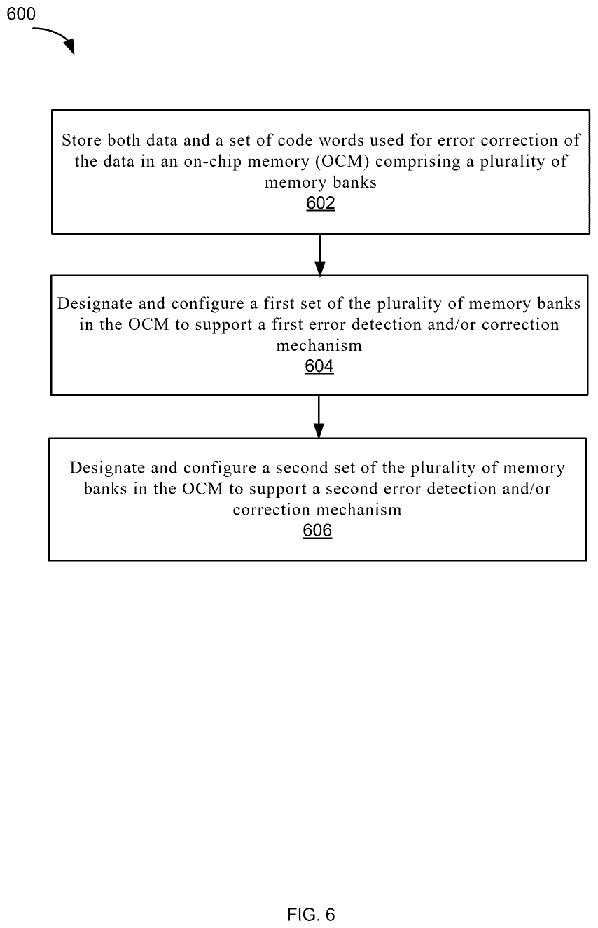

FIG. 6 depicts a flowchart 600 of an example of a process to support multiple error detection and/or correction mechanisms via flexible OCM configurations. Although the figure depicts functional steps in a particular order for purposes of illustration, the processes are not limited to any particular order or arrangement of steps. One skilled in the relevant art will appreciate that the various steps portrayed in this figure could be omitted, rearranged, combined and/or adapted in various ways.

In the example of FIG. 6, the flowchart 600 starts at block 602, where both data and a set of code words used for error correction of the data are stored in an on-chip memory (OCM) comprising a plurality of memory banks. The flowchart 600 continues to step 604, where a first set of the plurality of memory banks in the OCM is designated and configured to support a first error detection and/or correction mechanism. The flowchart 600 ends at step 606, where a second set of the plurality of memory banks in the OCM is designated and configured to support a second error detection and/or correction mechanism.

The foregoing description of various embodiments of the claimed subject matter has been provided for the purposes of illustration and description. It is not intended to be exhaustive or to limit the claimed subject matter to the precise forms disclosed. Many modifications and variations will be apparent to the practitioner skilled in the art. Embodiments were chosen and described in order to best describe the principles of the invention and its practical application, thereby enabling others skilled in the relevant art to understand the claimed subject matter, the various embodiments and the various modifications that are suited to the particular use contemplated.

What is claimed is:

1. An apparatus, comprising:
an on-chip memory (OCM) comprising a plurality of memory banks, wherein each of the plurality of memory banks is configured to store both data and a set of code words used for error correction of the data; and
an OCM configuration module configured to
designate and configure a first set of the plurality of memory banks in the OCM to support a first error detection and/or correction mechanism; and
designate and configure a second set of the plurality of memory banks in the OCM to support a second error detection and/or correction mechanism.

2. The apparatus of claim 1, further comprising:
a plurality of memory controllers each configured to control access to at least one of the plurality of memory banks of the OCM.

3. The apparatus of claim 1, wherein:
memory type of the OCM is static random-access memory (SRAM).

4. The apparatus of claim 1, wherein:
the first and/or the second error detection and/or correction mechanism is a Single bit Error Correction Double bit Error Detection (SECDED) mechanism.

5. The apparatus of claim 1, wherein:
the first and/or the second error detection and/or correction mechanism is a parity mechanism.

6. The apparatus of claim 1, wherein:
the first set of the plurality of memory banks and/or the second set of the plurality of memory banks are continuous memory banks in the OCM.

7. The apparatus of claim 6, wherein:
the OCM configuration module is configured to set a pointer to mark separation between the first set and the second set of the memory banks supporting the first and the second error detection and/or correction mechanisms in the OCM, respectively.

8. The apparatus of claim 7, wherein:
the OCM configuration module is configured to set the pointer in such way that the plurality of memory banks in the OCM are configured to support a single error detection and/or correction mechanism.

9. The apparatus of claim 7, wherein:
the OCM configuration module is configured to one of: (i) interleavingly map an address space to the plurality of memory banks based on the pointer, and (ii) sequentially map the address space to the plurality of memory banks based on the pointer.

10. The apparatus of claim 1, wherein:
one or more of the plurality of memory banks each comprise a plurality of memory instances configured to store data and a corresponding set of code words to support one of the first and the second error detection and/or correction mechanisms.

11. The apparatus of claim 10, wherein:
the OCM configuration module is configured to assign one or more of the plurality of memory instances to store one of: i) the data only, or ii) the code words only, and iii) both the data and the code words interleavingly.

12. The apparatus of claim 11, wherein:
the OCM configuration module is configured to assign certain un-used memory space between the data and the code words in each of one or more of the plurality of memory instances that store both the data and the code words.

13. An on-chip memory (OCM), comprising:
a plurality of memory banks, wherein each of the plurality of memory banks is configured to store both data and a set of code words used for error correction of the data; and wherein
a first set of the plurality of memory banks in the OCM are configured to support a first error detection and/or correction mechanism; and
a second set of the plurality of memory banks in the OCM are configured to support a second error detection and/or correction mechanism.

14. A method, comprising:
storing both data and a set of code words used for error correction of the data in an on-chip memory (OCM) comprising a plurality of memory banks;
designating and configuring a first set of the plurality of memory banks in the OCM to support a first error detection and/or correction mechanism; and
designating and configuring a second set of the plurality of memory banks in the OCM to support a second error detection and/or correction mechanism.

15. The method of claim 14, further comprising:
setting a pointer to mark separation between the first set and the second set of the memory banks supporting the first and the second error detection and/or correction mechanisms in the OCM, respectively, if the first set of the plurality of memory banks and/or the second set of the plurality of memory banks are continuous memory banks in the OCM.

16. The method of claim 15, further comprising:
setting the pointer in such way that the plurality of memory banks in the OCM are configured to support a single error detection and/or correction mechanism.

17. The method of claim 15, further comprising:
mapping an address space to the plurality of memory banks based on the pointer.

18. The method of claim 14, further comprising:
storing data and a corresponding set of code words in a plurality of memory instances in each of one or more of the plurality of memory banks to support one of the first and the second error detection and/or correction mechanisms.

19. The method of claim 18, further comprising:
assigning one or more of the plurality of memory instances to store one of: i) the data only, ii) the code words only, and iii) both the data and the code words interleavingly.

20. A system, comprising:
a means for storing both data and a set of code words used for error correction of the data in an on-chip memory (OCM) comprising a plurality of memory banks;
a means for designating and configuring a first set of the plurality of memory banks in the OCM to support a first error detection and/or correction mechanism; and
a means for designating and configuring a second set of the plurality of memory banks in the OCM to support a second error detection and/or correction mechanism.
